(19) United States
(12) Patent Application Publication
(10) Pub. No.: US 2016/0072320 A1
(43) Pub. Date: Mar. 10, 2016

(54) OVERCURRENT DETECTION DEVICE, AND CHARGING/DISCHARGING SYSTEM, DISTRIBUTION BOARD, CHARGING CONTROL DEVICE, CHARGING/DISCHARGING DEVICE FOR VEHICLE AND ELECTRICAL APPARATUS FOR VEHICLE, USING THE OVERCURRENT DETECTION DEVICE

(71) Applicant: PANASONIC INTELLECTUAL PROPERTY MANAGEMENT CO., LTD., Osaka (JP)

(72) Inventor: Masataka KANDA, Osaka (JP)

(21) Appl. No.: 14/783,817

(22) PCT Filed: Mar. 18, 2014
(86) PCT No.: PCT/JP2014/001538

§ 371 Date: Oct. 9, 2015

(30) Foreign Application Priority Data
Apr. 12, 2013 (JP) 2013-083585

(51) Int. Cl. H02J 7/00; G01R 19/165; H02H 9/02; H02H 7/18; H02H 3/08

(52) U.S. Cl. CPC H02J 7/0029; H02H 7/18; H02H 3/08; H02H 9/02; G01R 19/165; H02J 7/0052; H02J 7/007; H02J 7/0063; H02J 2007/0067

(57) ABSTRACT

A first threshold Vf1 that is compared with a measurement value of a charging current and a second threshold Vf2 that is compared with a measurement value of a discharging current are set to mutually different values by a determination unit 12. Also the first threshold Vf1 relating to the charging current is set to a value higher (greater) than the second threshold Vf2 relating to the discharging current.

### TECHNICAL FIELD

The present invention relates to an overcurrent detection device that detects an overcurrent when charging a storage battery and discharging from the storage battery to a load, and also relates to a charging/discharging system, a distribution board, a charging control device, a charging/discharging device for a vehicle, and an electrical apparatus for a vehicle, using the overcurrent detection device.

### BACKGROUND ART

Charging devices that connect an AC power grid and an electric automobile (inclusive of a plug-in hybrid vehicle) through a charging connector and charge the electric automobiles have been used for charging electric automobiles (see, for example, a control box described in JP 2010-110055 A, referred to hereinbelow as document 1). The charging device disclosed in document 1 has a function of detecting the occurrence of a current leak and cutting off an electric circuit (current leak cut-off function). A charging device is sometimes also provided with a function of cutting off an electric circuit when a very large current flows due to a failure (short circuit failure) of a charging connector (overcurrent cut-off function). More specifically, a relay contact is opened and an electric circuit is cut off when the detection value of a charging current is compared with a predetermined threshold and the detection value exceeds the threshold.

The so-called V2H (Vehicle-to-Home) in which the power of a storage battery installed on an electric automobile (onboard battery) is taken out and supplied to a load (electrical products, or the like) in a home have recently found practical use. In this case, a relatively large current is needed to shorten the charging time at the time of charging, but a current as large as the charging current is not needed at the time of discharging. Therefore, where the threshold for overcurrent detection is set to a value larger than the detection value of the normal charging current, adequate overcurrent protection sometimes cannot be attained at the time of discharging.

### DISCLOSURE OF THE INVENTION

Accordingly, it is an objective of the present invention to provide an overcurrent detection device that performs appropriate overcurrent detection during both the charging and the discharging, and also a charging/discharging system, a distribution board, a charging control device, a charging/discharging device for a vehicle and an electrical apparatus for a vehicle, using the overcurrent detection device.

An overcurrent detection device in accordance with the present invention includes a first measurement unit, a second measurement unit and a determination unit. The first measurement unit is configured to measure a magnitude of a charging current, which is supplied from a power source to a storage battery installed on a vehicle, as a first measurement value. The second measurement unit is configured to measure a magnitude of a discharging current, which is discharged from the storage battery to a load which is outside the vehicle, as a second measurement value. The determination unit is configured to compare the first measurement value with a first threshold, compare the second measurement value with a second threshold, determine that an abnormality is present when the first measurement value is equal to or greater than the first threshold, and determine that an abnormality is present when the second measurement value is equal to or greater than the second threshold. The first threshold and the second threshold are set to mutually different values.

In the overcurrent detection device, it is preferred that the first threshold be set higher than the second threshold.

It is preferred that the overcurrent detection device further include a cut-off unit configured to cut off an electric circuit in which the charging current and the discharging current flow. The cut-off unit is configured to cut off the electric circuit when the determination unit determines that an abnormality is present.

In the overcurrent detection device, it is preferred that the determination unit be constituted by a first determination unit configured to compare the first measurement value with the first threshold to determine the presence/absence of an abnormality, and a second determination unit configured to compare the second measurement value with the second threshold to determine the presence/absence of an abnormality.

It is preferred that the overcurrent detection device further include a current suppression unit configured to allow the charging current to flow to the first measurement unit and prevent the charging current from flowing to the second measurement unit when the storage battery is charged, and allow the discharging current to flow to the second measurement unit and prevent the discharging current from flowing to the first measurement unit when the storage battery is discharged.

In the overcurrent detection device, it is preferred that the current suppression unit include a first rectifying element connected in series with the first measurement unit and a second rectifying element connected in series with the second measurement unit. In this case, a series circuit of the first measurement unit and the first rectifying element and a series circuit of the second measurement unit and the second rectifying element are connected in parallel.

In the overcurrent detection device, it is preferred that the current suppression unit include a first switch connected in series with the first measurement unit and a second switch connected in series with the second measurement unit. In this case, a series circuit of the first measurement unit and the first switch and a series circuit of the second measurement unit and the second switch are connected in parallel.

A charging/discharging system in accordance with the present invention has any of the above-described overcurrent detection devices and a charging/discharging control device configured to adjust the charging current and the discharging current.

A distribution board in accordance with the present invention has any of the above-described overcurrent detection devices, a main switching device having a primary side connected to the power source, and one or a plurality of branched switching devices connected to a secondary side of the main switching device.

A charging/discharging control device in accordance with the present invention is provided with any of the above-described overcurrent detection devices, and a cable through which the charging current and discharging current flow.

A charging/discharging device for a vehicle in accordance with the present invention is provided with any of the above-described overcurrent detection devices, a cable through which the charging current and discharging current flow, and a housing that accommodates the overcharging detection device and can be connected to the vehicle.

An electrical apparatus for a vehicle in accordance with the present invention is provided with any of the above-described overcurrent detection devices, and is installed on the vehicle.

In the overcurrent detection device, and the charging/discharging system, the distribution board, the charging control device, the charging/discharging device for a vehicle, and the electrical apparatus for a vehicle, using the overcurrent detection device, in accordance with the present invention, the first threshold relating to the charging current and the second threshold relating to the discharging current are set to mutually different values. The resultant effect is that appropriate overcurrent detection can be performed during both the charging and the discharging.

### BRIEF DESCRIPTION OF THE DRAWINGS

The preferred embodiments of the present invention will be described hereinbelow in greater detail. Other features and merits of the present invention will be better understood in relation to the following detailed description and appended drawings.

FIG. 1 is a block diagram illustrating a charging/discharging system according to an embodiment.

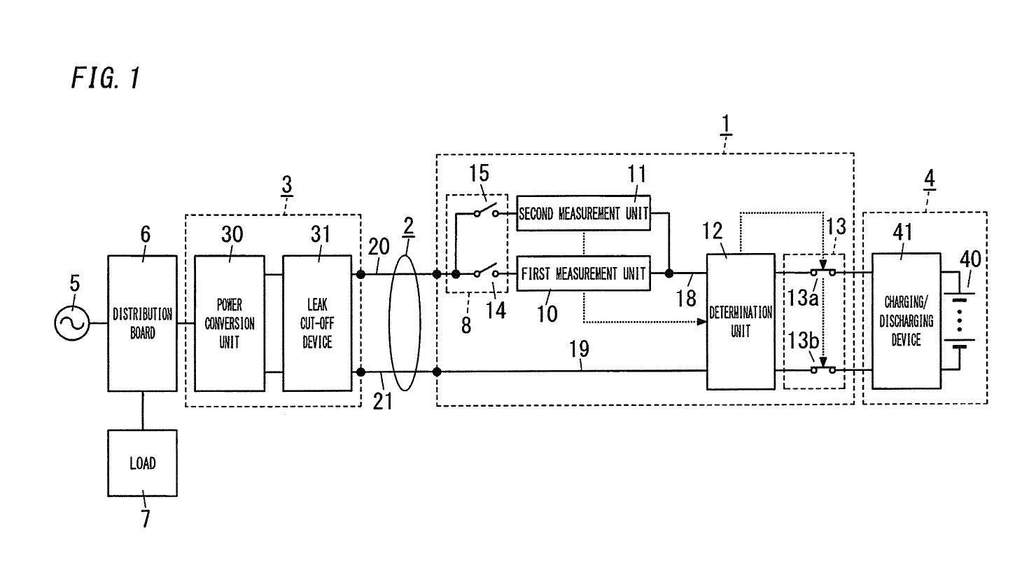

FIG. 2 is a circuit configuration diagram of a determination unit of an overcurrent detection device provided in the charging/discharging system according to the embodiment.

FIG. 3 is a block diagram illustrating another charging/discharging system according to the embodiment.

### EMBODIMENT FOR CARRYING OUT THE INVENTION

An overcurrent detection device and a charging/discharging system of the present embodiment in accordance with the present invention will be explained hereinbelow in detail with reference to the drawings. An electric automobile is considered by way of example as a vehicle for installing a storage battery in the present embodiment, but the vehicle may also be other than the electric automobile.

The charging/discharging system of the present embodiment has a connector 1, a cable 2, and a charging/discharging control device 3. The charging/discharging control device 3 is connected to a commercial power grid 5 through a distribution board (for example, home distribution board) 6, connected to a load (for example, an electrical device in the home) 7 through the distribution board 6, and to an electric automobile 4 through the cable 2 and the connector 1.

The electric automobile 4 is provided with a storage battery (onboard battery) 40 for propulsion power, an inlet (not depicted in the figure) into which the connector 1 can be removably inserted, and a charging/discharging device 41 that performs charging of the onboard battery 40 and discharging of the onboard battery 40. The charging/discharging device 41 is provided, for example, with a bidirectional AC/DC converter. The charging/discharging device 41 converts the AC power supplied from the charging/discharging control device 3 into DC power to charge the onboard battery 40, and converts the DC power discharged from the onboard battery 40 into the AC power and outputs the converted power to the charging/discharging control device 3.

The charging/discharging control device 3 has, for example, a power conversion unit 30 and a current leak cut-off device 31. The power conversion unit 30 is constituted, for example, by an insulated transformer or bidirectional insulated AC/AC converter, insulates the power-grid side (distribution board 6 side as viewed from the power conversion unit 30) and the non-power-grid side (electric automobile 4 side as viewed from the power conversion unit 30) and also provides AC power bidirectionally.

The current leak cut-off device 31 compares the electric current outputted from one terminal of the power conversion unit 30 on the non-power-grid side and the electric current returning to the other terminal of the power conversion unit 30 on the non-power-grid side, determines that a current leak has occurred when the difference between the currents exceeds a predetermined threshold, and cuts off the electric circuit.

The cable 2 is constituted by a multicore electrical cable in which a pair of feed wires 20, 21 in which the currents (charging current and discharging current) flow and a ground wire (not depicted in the figure) are covered with an insulating sheath. One end of the cable 2 is connected to the charging/discharging control device 3 (current leak cut-off device 31), and the connector 1 is provided at the other end of the cable 2. The connector 1 is a plug connector that is connected, by removable insertion, with the inlet (receptacle connector) of the electric automobile 4.

The connector 1 is constituted by accommodating a first measurement unit 10, a second measurement unit 11, a determination unit 12, a cut-off unit 13, and a current suppression unit 8 (a first switch 14 and a second switch 15) in a housing (not depicted in the figure). The first measurement unit 10 measures the magnitude of the charging current, which is supplied to the onboard battery 40, as the first measurement value. The second measurement unit 11 measures the magnitude of the discharging current, which is discharged from the onboard battery 40, as the second measurement value. The first measurement unit 10, the second measurement unit 11, the determination unit 12, the cut-off unit 13, and the current suppression unit 8 constitute an overcurrent detection device.

The first measurement unit 10 is inserted through the first switch 14 into the feed circuit 18 (electric circuit conductively connected to the feed circuit 20) from among the feed circuit 18 and a feed circuit 19. The second measurement unit 11 is inserted through the second switch 15 into the feed circuit 18 in parallel with the first measurement unit 10. The first measurement unit 10 and the second measurement unit 11 have a common circuit configuration, and for example measure the terminal voltage (absolute value) of a detection resistor inserted into the feed circuit 18, or use a current sensor and directly measure the magnitude (absolute value) of the current flowing in the feed circuit 18. The first measurement unit 10 and the second measurement unit 11 output the DC voltage signals corresponding to the respective measurement values to the determination unit 12.

The first switch 14 and the second switch 15 are configured, for example, to be ON/OFF switched by operating an operation member (not shown in the figure) provided in the housing. In other words, where the operation member is operated from a discharge position to a charge position, the first switch 14 is set ON and the second switch 15 is set OFF, and where the operation member is operated from the charge position to the discharge position, the first switch 14 is set OFF and the second switch 15 is set ON. However, the charging/discharging control device 3 may also switch the first switch 14 and the second switch 15 by remote operation.

The cut-off unit 13 is constituted by a pair of contacts 13a, 13b, which are inserted into the two feed circuits 18, 19, respectively, and configured to cut off the feed circuits 18, 19 by opening the contacts 13a, 13b.

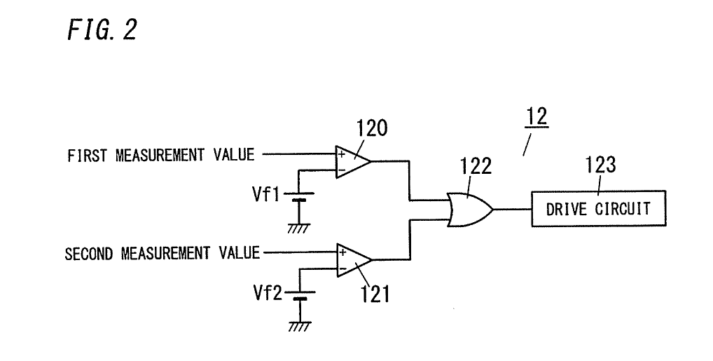

For example, as depicted in FIG. 2, the determination unit 12 is constituted by first and second comparators 120, 121, an OR gate 122 that computes a logical sum of the outputs of the first and second comparators 120, 121, and a drive circuit 123 that drives the cut-off unit 13 in response to the output of the OR gate 122. The first comparator 120 compares the first measurement value (DC voltage signal level) with a first threshold Vf1. When the first measurement value is less than the first threshold Vf1, the output is set to a low level, and when the first measurement value is equal to or greater than the first threshold Vf1, the output is set to a high level. The second comparator 121 compares the second measurement value (DC voltage signal level) with a second threshold Vf2. When the second measurement value is less than the second threshold Vf2, the output is set to a low level, and when the second measurement value is equal to or greater than the second threshold Vf2, the output is set to a high level. Thus, in the present embodiment, the first comparator 120 corresponds to the first determination unit, and the second comparator 121 corresponds to the second determination unit. However, it is desirable that integrators be respectively connected to plus input terminals of the first and second comparators 120, 121 and the DC voltage signal levels after integration with the integrators be respectively compared with the first and second threshold Vf1, Vf2.

Where at least either one output of the first and second comparators 120, 121 is at a high level, the output of the OR gate 122 is set to a high level, and where the outputs of the first and second comparators 120, 121 are both at a low level, the output is set to a low level. A drive circuit 123 is configured to drive the cut-off unit 13 and close the pair of contacts 13a, 13b when the output of the OR gate 122 is at a low level, and to stop the drive of the cut-off unit 13 and open the pair of contacts 13a, 13b when the output of the OR gate 122 is at a high level.

The operation of the present embodiment will be explained hereinbelow.

Initially, the case is considered in which the electric automobile 4 is charged. When the electric automobile 4 is charged, the AC power supplied from the power grid 5 is supplied from the power conversion unit 30 to the electric automobile 4 through the cable 2 and the connector 1, and the onboard battery 40 is charged by the charging/discharging device 41 installed on the electric automobile 4. In this case, the first switch 14 is switched ON and the second switch 15 is switched OFF. Therefore, the first measurement unit 10 outputs a DC voltage signal (first measurement value) corresponding to the magnitude of the charging current, and the DC voltage signal (second measurement value) of the second measurement unit 11 is zero volts at all times.

Where an excessively large current continues flowing during charging of the electric automobile 4, the output of the first comparator 120 of the determination unit 12 rises from the low level to the high level. Since the output of the OR gate 122 then also rises from the low level to the high level, the drive circuit 123 stops the drive of the cut-off unit 13 and opens the contacts 13a, 13b. As a result, the cut-off unit 13 cuts off the feed circuits 18, 19 and stops the supply of the charging current to the electric automobile 4.

Meanwhile, in the case of discharging from the electric automobile 4, the DC power discharged from the onboard battery 40 is converted by the charging/discharging device 41 into AC power which is inputted to the power conversion unit 30 through the connector 1 and the cable 2, converted with the power conversion unit 30, and supplied to the load 7 through the distribution board 6. In this case, the first switch 14 is switched OFF and the second switch 15 is switched ON. Therefore, the DC voltage signal (first measurement value) of the first measurement unit 10 is zero volts at all times and the second measurement unit 11 outputs a DC voltage signal (second measurement value) corresponding to the magnitude of the discharging current.

Where an excessively large current continues flowing during discharging of the electric automobile 4, the output of the second comparator 121 of the determination unit 12 rises from the low level to the high level. Since the output of the OR gate 122 then also rises from the low level to the high level, the drive circuit 123 stops the drive of the cut-off unit 13 and opens the contacts 13a, 13b. As a result, the cut-off unit 13 cuts off the feed circuits 18, 19 and stops the supply of the discharging current of the electric automobile 4.

However, it is desirable that the charging current be relatively large in order to shorten the charging time of the onboard battery 40. By contrast, it is desirable that the discharging current be less than the charging current in order to extend the power feed time of the load 7. Therefore, in the determination unit 12 in the present embodiment, the first threshold Vf1 relating to the charging current is set to a value which is higher (greater) than the second threshold Vf2 relating to the discharging current.

As mentioned hereinabove, the first threshold Vf1 that is compared by the determination unit 12 with the measurement value of the charging current and the second threshold Vf2 that is compared with the measurement value of the discharging current are set to mutually different values. Therefore, appropriate overcurrent detection can be performed during both the charging and the discharging. Further, since the first threshold Vf1 relating to the charging current is set to a value which is higher (greater) than the second threshold Vf2 relating to the discharging current, it is possible to shorten the charging time, extend the discharging time, and suppress the degradation of the onboard battery 40 at the time of discharging.

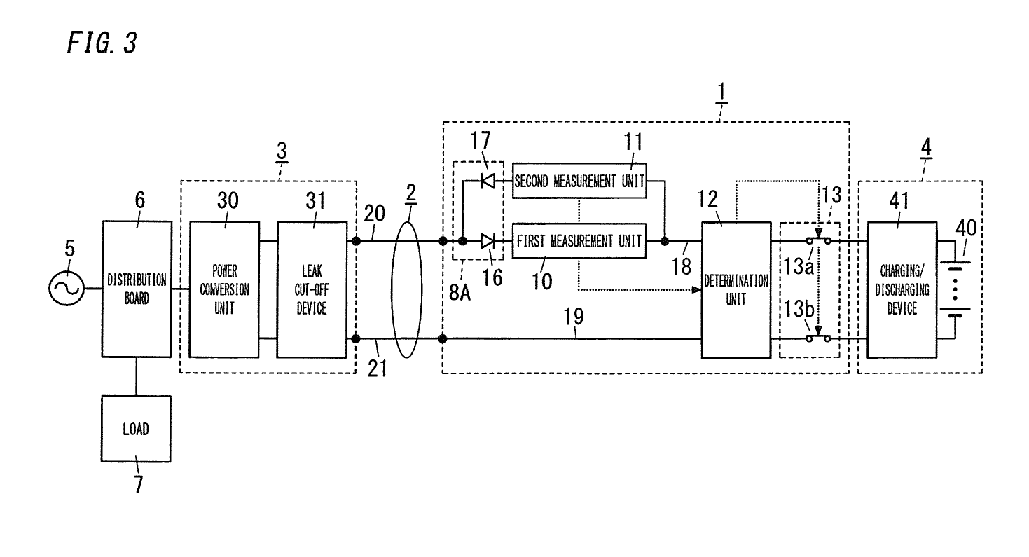

The above-described charging/discharging system of the present embodiment has the configuration in which AC power is exchanged between the charging/discharging control device 3 and the electric automobile 4. However, the charging/discharging system of the present embodiment is not limited to such a configuration and may be configured to exchange DC power between the charging/discharging control device 3 and the electric automobile 4. In other words, the power conversion unit 30 of the charging/discharging control device 3 may be constituted by a bidirectional AC/DC converter, the charging/discharging device 41 of the electric automobile 4 may charge the onboard battery 40 with the DC power outputted from the power conversion unit 30, and the DC power discharged from the onboard battery 40 may be outputted to the charging/discharging control device 3. In this case, a current suppression unit 8A equipped with a first rectifying element (diode) 16 and a second rectifying element (diode) 17 can be used instead of the current suppression unit 8 equipped with the first switch 14 and the second switch 15 (see FIG. 3).

Further, in the present embodiment, the case is described in which the overcurrent detection device is accommodated in the housing of the connector 1, but the overcurrent detection device may be also accommodated in a housing provided at the cable 2, rather than in the housing of the connector 1. Alternatively, the overcurrent detection device may be also accommodated in the box of the distribution board 6 together with the main switching device or branch switching device, or may be provided at the charging/discharging control device 3. Yet another option is to install the overcurrent detection device at the electric automobile 4.

As described hereinabove, the overcurrent detection device of the present embodiment includes the first measurement unit 10, the second measurement unit 11, and the determination unit 12. The first measurement unit 10 is configured to measure the magnitude of the charging current, which is supplied from a power source (power grid 5) to a storage battery (onboard battery 40) installed on a vehicle, as a first measurement value. The second measurement unit 11 is configured to measure the magnitude of the discharging current, which is discharged from the storage battery (onboard battery 40) to the load 7 outside the vehicle, as a second measurement value. The determination unit 12 is configured to compare the first measurement value with the first threshold Vf1, compare the second measurement value with the second threshold Vf2, determine that an abnormality is present when the first measurement value is equal to or greater than the first threshold Vf1, and determine that an abnormality is present when the second measurement value is equal to or greater than the second threshold Vf2. The first threshold Vf1 and the second threshold Vf2 are set to mutually different values.

In the overcurrent detection device, it is preferred that the first threshold Vf1 be set higher than the second threshold Vf2.

It is preferred that the overcurrent detection device further include the cut-off unit 13 configured to cut off an electric circuit in which the charging current and the discharging current flow. In this case, the cut-off unit 13 is configured to cut off the electric circuit when the determination unit 12 determines that an abnormality is present.

In the overcurrent detection device, it is preferred that the determination unit 12 be constituted by a first determination unit (first comparator 120) and a second determination unit (second comparator 121). In this case, the first determination unit is configured to compare the first measurement value with the first threshold Vf1 to determine the presence/absence of an abnormality, and the second determination unit is configured to compare the second measurement value with the second threshold Vf2 to determine the presence/absence of an abnormality.

It is preferred that the overcurrent detection device further include the current suppression unit 8 (or current suppression unit 8A) configured to allow the charging current to flow to the first measurement unit 10 and prevent the charging current from flowing to the second measurement unit 11 when the storage battery is charged, and allow the discharging current to flow to the second measurement unit 11 and prevent the discharging current from flowing to the first measurement unit 10 when the storage battery is discharged.

In the overcurrent detection device, is preferred that the current suppression unit 8A include the first rectifying element 16 connected in series with the first measurement unit 10 and the second rectifying element 17 connected in series with the second measurement unit 11. In this case, the series circuit of the first measurement unit 10 and the first rectifying element 16 and the series circuit of the second measurement unit 11 and the second rectifying element 17 are connected in parallel.

In the overcurrent detection device, it is preferred that the current suppression unit 8 include the first switch 14 connected in series with the first measurement unit 10 and the second switch 15 connected in series with the second measurement unit 11. In this case, the series circuit of the first measurement unit 10 and the first switch 14 and the series circuit of the second measurement unit 11 and the second switch 15 are connected in parallel.

The charging/discharging system of the present embodiment has any of the above-described overcurrent detection devices, and a charging/discharging control device configured to adjust the charging current and the discharging current.

The distribution board of the present embodiment has any of the above-described overcurrent detection devices, a main switching device having the primary side connected to the power source (power grid 5), and one or a plurality of branched switching devices connected to the secondary side of the main switching device.

The charging/discharging control device of the present embodiment is provided with any of the above-described overcurrent detection devices, and a cable through which the charging current and discharging current flow.

The charging/discharging device for a vehicle of the present embodiment is provided with any of the above-described overcurrent detection devices, a cable through which the charging current and discharging current flow, and a housing that accommodates the overcharging detection device and can be connected to the vehicle.

The electrical apparatus for a vehicle of the present embodiment is provided with any of the above-described overcurrent detection devices, and is installed on the vehicle.

The present invention is explained hereinabove on the basis of several preferred embodiments thereof, but various modifications and changes thereof can be made by a person skilled in the art, without departing from the spirit and scope of the invention, that is, from the claims.

1. An overcurrent detection device comprising:
a first measurement unit configured to measure a magnitude of a charging current, which is supplied from a power source to a storage battery installed on a vehicle, as a first measurement value;
a second measurement unit configured to measure a magnitude of a discharging current, which is discharged from the storage battery to a load which is outside the vehicle, as a second measurement value; and
a determination unit configured to compare the first measurement value with a first threshold, compare the second measurement value with a second threshold, determine that an abnormality is present when the first measurement value is equal to or greater than the first threshold, and determine that an abnormality is present when the second measurement value is equal to or greater than the second threshold,
the first threshold and the second threshold being set to mutually different values.

2. The overcurrent detection device according to claim 1, wherein the first threshold is set to a value higher than the second threshold.

3. The overcurrent detection device according to claim 1, further comprising a cut-off unit configured to cut off an electric circuit in which the charging current and the discharging current flow,
wherein the cut-off unit is configured to cut off the electric circuit when the determination unit determines that an abnormality is present.

4. The overcurrent detection device according to claim 1, wherein the determination unit is constituted by a first determination unit configured to compare the first measurement value with the first threshold to determine presence/absence of an abnormality, and a second determination unit configured to compare the second measurement value with the second threshold to determine presence/absence of an abnormality.

5. The overcurrent detection device according to claim 1, further comprising a current suppression unit configured to allow the charging current to flow to the first measurement unit and prevent the charging current from flowing to the second measurement unit when the storage battery is charged, and allow the discharging current to flow to the second measurement unit and prevent the discharging current from flowing to the first measurement unit when the storage battery is discharged.

6. The overcurrent detection device according to claim 5, wherein:
the current suppression unit includes a first rectifying element connected in series with the first measurement unit and a second rectifying element connected in series with the second measurement unit; and
a series circuit of the first measurement unit and the first rectifying element and a series circuit of the second measurement unit and the second rectifying element are connected in parallel.

7. The overcurrent detection device according to claim 5, wherein:
the current suppression unit includes a first switch connected in series with the first measurement unit and a second switch connected in series with the second measurement unit; and
a series circuit of the first measurement unit and the first switch and a series circuit of the second measurement unit and the second switch are connected in parallel.

8. A charging/discharging system having the overcurrent detection device according to claim 1 and a charging/discharging control device configured to adjust the charging current and the discharging current.

9. A distribution board having the overcurrent detection device according to claim 1, a main switching device having a primary side connected to the power source, and one or a plurality of branched switching devices connected to a secondary side of the main switching device.

10. A charging/discharging control device provided with the overcurrent detection device according to claim 1 and a cable through which the charging current and discharging current flow.

11. A charging/discharging device for a vehicle provided with the overcurrent detection device according to claim 1, a cable through which the charging current and discharging current flow, and a housing that accommodates the overcharging detection device and can be connected to the vehicle.

12. An electrical apparatus for a vehicle which is provided with the overcurrent detection device according to claim 1 and installed on the vehicle.

13. The overcurrent detection device according to claim 2, further comprising a cut-off unit configured to cut off an electric circuit in which the charging current and the discharging current flow,
wherein the cut-off unit is configured to cut off the electric circuit when the determination unit determines that an abnormality is present.

14. The overcurrent detection device according to claim 2, wherein the determination unit is constituted by a first determination unit configured to compare the first measurement value with the first threshold to determine presence/absence of an abnormality, and a second determination unit configured to compare the second measurement value with the second threshold to determine presence/absence of an abnormality.

15. The overcurrent detection device according to claim 3, wherein the determination unit is constituted by a first determination unit configured to compare the first measurement value with the first threshold to determine presence/absence of an abnormality, and a second determination unit configured to compare the second measurement value with the second threshold to determine presence/absence of an abnormality.
